(19) United States
(12) Patent Application Publication
(10) Pub. No.: US 2025/0072169 A1
(43) Pub. Date: Feb. 27, 2025

(54) LIGHT EMITTING DIODE

(71) Applicant: Taiwan-Asia Semiconductor Corporation, Hsinchu City (TW)

(72) Inventors: Ching-Yuan TSAI, Hsinchu City (TW); Hong-Ta CHENG, Hsinchu City (TW); Yao-Hong HUANG, Hsinchu City (TW)

(21) Appl. No.: 18/512,642

(22) Filed: Nov. 17, 2023

(30) Foreign Application Priority Data
Aug. 24, 2023 (TW) 112131904

(51) Int. Cl. H01L 33/38; H01L 33/00; H01L 33/40; H01L 33/46

(52) U.S. Cl. CPC H01L 33/38; H01L 33/0025; H01L 33/40; H01L 33/46; H01L 33/22

(57) ABSTRACT

The present invention relates to a light emitting diode (LED) which comprises multiple point-like conductive electrodes, a dielectric layer, and an epitaxial composite layer. The dielectric layer is disposed around each point-like conductive electrode, and the epitaxial composite layer is disposed both on the point-like conductive electrodes and the dielectric layer. Each point-like conductive electrode includes an ohmic-contact metal layer and a carbon-doped gallium arsenide epitaxial layer. The carbon-doped gallium arsenide epitaxial layer is disposed on the ohmic-contact metal layer and electrically connected to the epitaxial composite layer.

### CROSS-REFERENCES TO RELATED APPLICATIONS

This application claims the benefit of priority to Taiwanese Patent Application No. 112131904 filed on Aug. 24, 2023, which is hereby incorporated by reference in its entirety.

### BACKGROUND OF THE INVENTION

### Field of the Invention

The present invention relates to a light emitting diode, in particular to a light emitting diode with high brightness.

### Descriptions of the Related Art

Light Emitting Diode (hereinafter referred to as LED) has the advantages of high brightness, small size, low power consumption and long life, and is widely used in lighting or display products. In conventional short-wave infrared light emitting diodes (SWIR LEDs), in pursuit of the goals of developing different size specifications and improving brightness, conventional technologies usually use P-type ohmic-contact metal and specular reflection system in the light emitting diode structure. Different structural tests will be performed to improve light reflection and extraction efficiency. Specifically, please refer to FIG. 1, which shows a currently common quaternary infrared light emitting diode 1 in the 850˜1100 nanometer (nm) band. The structure of this type of light emitting diode 1 has a transition layer 10, a P-type semiconductor layer 20 of magnesium (Mg) doped gallium phosphide (GaP), and a P-type semiconductor layer 30 of carbon (C) doped gallium phosphide (GaP). This type of light emitting diode 1 uses a transition layer 10 to adjust the lattice mismatch between the magnesium-doped gallium phosphide epitaxial layer 20 and the upper aluminum indium phosphide epitaxial layer 40. Moreover, magnesium-doped gallium phosphide epitaxial layer 20 serves as a current spreading layer to achieve the effect of current spreading and enhance the brightness. The carbon-doped gallium phosphide epitaxial layer 30 serves as a P-type ohmic-contact layer to electrically connect the lower metal electrode 50. However, the entire structure of the carbon-doped gallium phosphide epitaxial layer 30 has a light absorption effect, which affects the brightness. Moreover, since the carbon-doped gallium phosphide epitaxial layer 30 and the upper magnesium-doped gallium phosphide epitaxial layer 20 belong to the same epitaxial material, the carbon-doped gallium phosphide epitaxial layer 30 cannot be patterned to reduce its partial area for reducing the light absorption effect of the entire structure of the carbon-doped gallium phosphide epitaxial layer 30.

In order to overcome the above problems, the industry urgently needs an innovative light emitting diode structure and its manufacturing process to increase brightness while improving the problems of complex manufacturing process, high cost, and high forward voltage.

### SUMMARY OF THE INVENTION

One main objective of the present invention is to provide a high-brightness light emitting diode with simplified process steps and reduced costs. Through a new mirror structure, the light extraction efficiency is improved, thereby addressing the issues of low brightness, complex processes, high costs, and excessive forward voltage associated with conventional light emitting diode structures.

To achieve the above objective, the present invention provides a light emitting diode which comprises multiple point-like conductive electrodes, a dielectric layer, and an epitaxial composite layer. The dielectric layer is disposed around each point-like conductive electrode, and the epitaxial composite layer is disposed both on the point-like conductive electrodes and the dielectric layer. Each point-like conductive electrode includes an ohmic-contact metal layer and a carbon-doped gallium arsenide epitaxial layer. The carbon-doped gallium arsenide epitaxial layer is disposed on the ohmic-contact metal layer and electrically connected to the epitaxial composite layer.

In one embodiment of the light emitting diode of the present invention, the epitaxial composite layer includes a first semiconductor layer, a light-emitting layer, a second semiconductor layer and a third semiconductor layer, wherein the third semiconductor layer is electrically connected to the carbon-doped gallium arsenide epitaxial layer, the second semiconductor layer is disposed on the third semiconductor, the light-emitting layer is disposed on the second semiconductor layer, and the first semiconductor layer is disposed on the light-emitting layer.

In one embodiment of the light emitting diode of the present invention, the first semiconductor layer is an N-type aluminum gallium arsenide (AlGaAs) epitaxial layer, and the second semiconductor layer is a P-type aluminum gallium arsenide (AlGaAs) epitaxial layer, and the third semiconductor layer is a P-type aluminum indium phosphide (AlInP) epitaxial layer.

In one embodiment of the light emitting diode of the present invention, the ratio of the total distribution area of the point-like conductive electrodes to the area of the epitaxial composite layer is about 2.8% to 5.2%.

In one embodiment of the light emitting diode of the present invention, the thickness of the carbon-doped gallium arsenide epitaxial layer in each of the point-like conductive electrodes is about 100˜1000 angstroms (Å).

In one embodiment of the light emitting diode of the present invention, the carbon-doping concentration of the carbon-doped gallium arsenide epitaxial layer in each of the point-like conduction electrodes is about 4.0*E19˜1.5*E20.

In one embodiment of the light emitting diode of the present invention, the light emitting diode further comprises a reflective layer, wherein the dielectric layer and the point-like conductive electrodes are disposed on the reflective layer.

In one embodiment of the light emitting diode of the present invention, the reflective layer includes a transparent conductive layer and a reflective metal layer, and the transparent conductive layer is disposed on the reflective metal layer.

In one embodiment of the light emitting diode of the present invention, the transparent conductive layer is made of indium tin oxide, zinc aluminum oxide, zinc tin oxide, nickel oxide, cadmium tin oxide, antimony tin oxide or the combination thereof.

In one embodiment of the light emitting diode of the present invention, the light emitting diode further comprises a substrate, wherein the reflective layer is disposed on the substrate.

In one embodiment of the light emitting diode of the present invention, the ohmic-contact metal layer is made of gold (Au), silver (Ag), aluminum (Al), beryllium gold (BeAu), germanium gold (GeAu), zinc gold (AuZn) or the combination thereof.

In one embodiment of the light emitting diode of the present invention, the light emitting diode further comprises an upper electrode disposed on the epitaxial composite layer and does not vertically overlap with the point-like conductive electrodes.

After reviewing the diagrams and subsequent descriptions, those skilled in the art will readily understand other objectives of the present invention, as well as the technical means and embodiments of the present invention.

### BRIEF DESCRIPTION OF THE DRAWINGS

FIG. 1 is a schematic diagram of a known light emitting diode structure.

FIG. 2 to FIG. 11 are process flow diagrams of a light emitting diode in one embodiment of the present invention.

FIG. 12 is a top view of the light emitting diode structure in one embodiment of the present invention.

### DETAILED DESCRIPTION OF THE PREFERRED EMBODIMENT

The content of the present invention will be explained through embodiments below. The embodiments of the present invention are not intended to limit the implementation of the present invention to any specific environment, application, or particular manner as described in the embodiments. Therefore, the description of the embodiments is only to elucidate the purpose of the present invention, and not to limit the present invention. It should be noted that in the following embodiments and figures, components not directly related to the present invention have been omitted and not shown. The dimensional relationships between the components in the figures are provided for ease of understanding and are not intended to limit the actual proportions.

Please refer to FIG. 2, which discloses one embodiment of manufacturing a light emitting diode, particularly taking a short-wave infrared light emitting diode as an example. Specifically, gallium arsenide (GaAs) is used, for example, as an epitaxial growth substrate 100. Subsequently, an epitaxial composite layer is formed on the gallium arsenide substrate, which can be a double heterojunction structure of aluminum gallium arsenide (AlGaAs). Specifically, in this embodiment, the double heterojunction structure includes a first semiconductor layer 110, a light-emitting layer 120 formed on the first semiconductor layer 110, a second semiconductor layer 130 formed on the light-emitting layer 120, and a third semiconductor layer 140 formed on the second semiconductor layer 130. The light-emitting layer 120 is formed as a multiple quantum well (MQW) structure. In this embodiment, the emission wavelength range of the multiple quantum wells can be 1000˜1200 nanometers (nm). The first semiconductor layer 110 is an N-type aluminum gallium arsenide (AlGaAs) epitaxial layer, the second semiconductor layer 130 is a P-type aluminum gallium arsenide (AlGaAs) epitaxial layer, and the third semiconductor layer 140 is a P-type aluminum indium phosphide (AlInP) epitaxial layer. It should be noted that the materials mentioned in the above embodiment are just an example, and the present invention is not limited to this. In actual applications, the materials and their compositions can be adjusted according to the emission wavelength. For example, the epitaxial layers can be selected from a group consisting of aluminum gallium indium phosphide (AlGaInP), indium gallium phosphide (InGaP), aluminum gallium arsenide (AlGaAs), indium gallium arsenide (InGaAs), indium phosphide (InP) or the combination thereof.

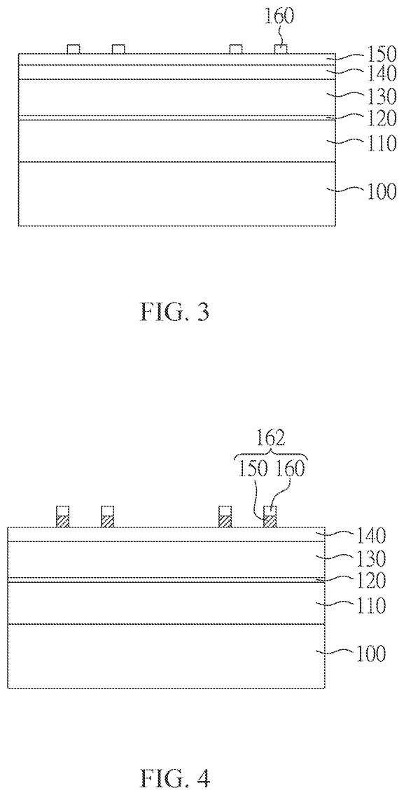

Please continue to refer to FIG. 2. On the third semiconductor layer 140, a P-type carbon (C) doped gallium arsenide (GaAs) epitaxial layer 150 is formed. It should be noted that there is no lattice mismatch issue between this carbon-doped gallium arsenide epitaxial layer 150 and the upper aluminum indium phosphide epitaxial layer 140, so the transition layer of the conventional structure can be omitted. Next, a metal plating process and a photolithography etching process are performed on the carbon-doped gallium arsenide epitaxial layer 150 to form a patterned ohmic-contact metal layer 160. Specifically, this ohmic-contact metal layer 160 can be made of gold (Au), silver (Ag), aluminum (Al), beryllium gold (BeAu), germanium gold (GeAu), zinc gold (AuZn), or a combination thereof, as shown in FIG. 3. Then, please refer to FIG. 4. Using the patterned ohmic-contact metal layer 160 as a hard mask, the carbon-doped gallium arsenide epitaxial layer 150 is directly etched, so that the patterned structure and the distribution area of the patterned carbon-doped gallium arsenide epitaxial layer 150 and those of the ohmic-contact metal layer 160 are the same. Moreover, multiple point-like conductive electrodes 162 are formed, which are electrically connected to the third semiconductor layer 140. In a preferred embodiment of the present invention, the thickness of the carbon-doped gallium arsenide epitaxial layer 150 in each point-like conductive electrode 162 of the light emitting diode is about 100˜1000 angstroms (Å). Moreover, the carbon-doping concentration of the carbon-doped gallium arsenide epitaxial layer is about 4.0*E19˜1.5*E20.

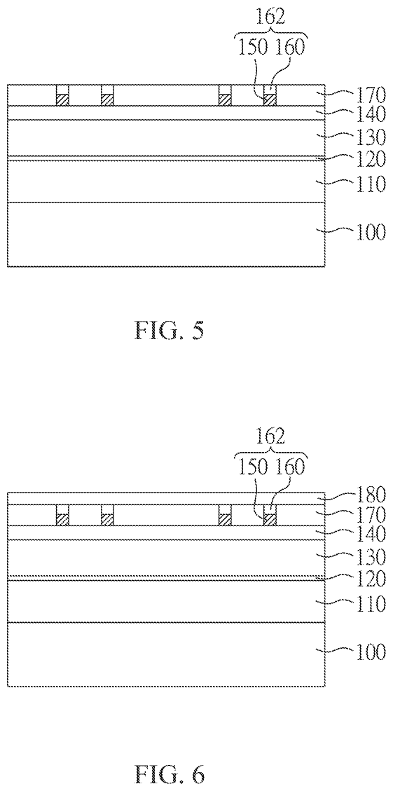

Please refer to FIG. 5. After depositing a dielectric layer 170 to cover the entire wafer surface, a photolithography etching process is used to remove part of the dielectric layer 170 until the ohmic-contact metal layer 160 in the point-like conductive electrodes 162 is exposed. Specifically, the dielectric layer 170 is a low refractive index dielectric layer, and its material can be silicon dioxide (SiO₂), silicon nitride (Si₃N₄), and the like. As shown in FIG. 6, a transparent conductive layer 180 is formed on the wafer surface by vapor deposition to cover the exposed ohmic-contact metal layer 160 and the dielectric layer 170, and it is electrically connected to the ohmic-contact metal layer 160. The materials of the transparent conductive layer 180 can be selected from a group consisting of indium tin oxide (ITO), aluminum-doped zinc oxide (AZO), indium-doped zinc oxide (IZO), nickel oxide, cadmium tin oxide, antimony tin oxide, and their combination.

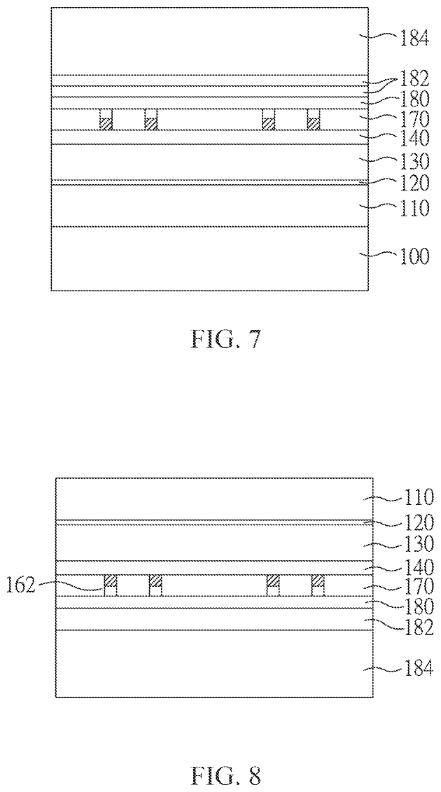

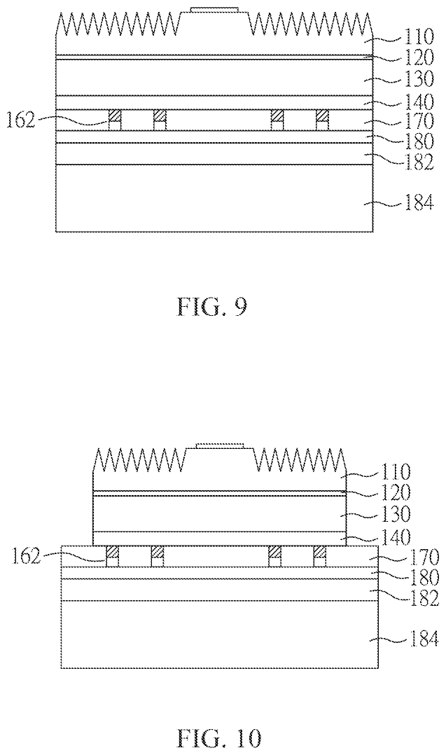

Please refer to FIG. 7. After depositing a reflective bonding metal layer 182 on the transparent conductive layer 180, a metal bonding process is performed to bond the reflective bonding metal layer 182 on the transparent conductive layer 180 to another reflective bonding metal layers 182 on a permanent bonding substrate 184. The transparent conductive layer 180 and the reflective bonding metal layer 182 serve as the mirror system of the reflective layer in the light emitting diode structure of the present invention. This system reflects the light emitted from the light-emitting layer upwards to enhance light extraction efficiency. The bonding metal material can be gold (Au), indium-gold (InAu) alloy, or the like, and the permanent bonding substrate 184 can be, but not limited to, a silicon substrate or a sapphire substrate. Next, please refer to FIG. 8. Remove the gallium arsenide epitaxial substrate 100 to expose the N-type first semiconductor layer 110, and flip it so that the permanent bonding substrate 184 is disposed at the bottom of the light emitting diode structure. Subsequently, as shown in FIG. 9, define a planar region for the subsequent formation of the upper electrode on the N-type first semiconductor layer 110, and perform roughening treatment on the remaining portion of the N-type first semiconductor layer 110. Then, as shown in FIG. 10, perform a MESA process for etching part of the epitaxial composite layer, i.e., etching part of the N-type first semiconductor layer 110, the light-emitting layer 120, the P-type second semiconductor layer 130, and the P-type third semiconductor layer 140, to expose part of the dielectric layer 170 and form a protective layer on the surface of the dielectric layer 170 and the roughened surface of the first semiconductor layer 110 (not shown in the figure). Finally, a cutting path is formed on the substrate. In a preferred embodiment of the present invention, the total distribution area of the point-like conductive electrodes 162 in the light emitting diode of the present invention is about 2.8% to 5.2% relative to the area of the epitaxial composite layer after the MESA process.

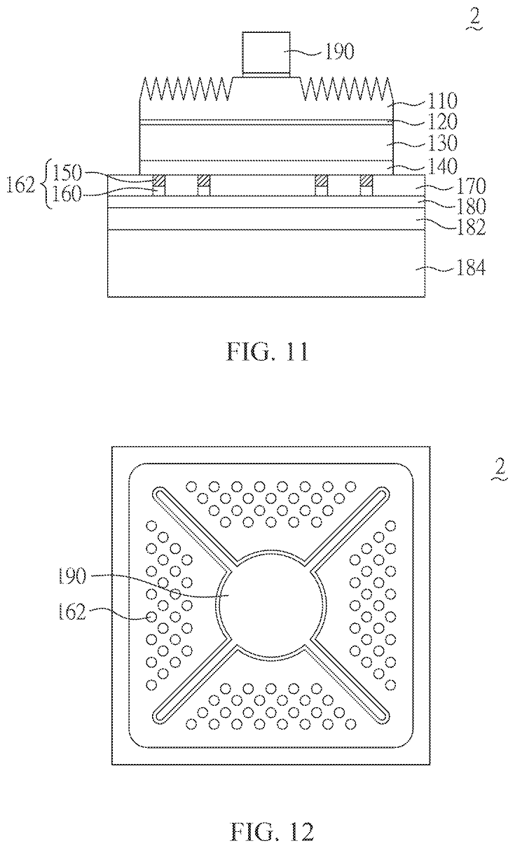

Please refer to FIG. 11, where a patterned N-type upper electrode 190 is formed on the planar region of the first semiconductor layer 110 to create a final structure of the light emitting diode 2 of the present invention. The material of the upper electrode 190 can be germanium gold (GeAu), germanium gold nickel (GeAuNi), or their combination. In particular, the upper electrode 190 does not overlap in the vertical position with the plurality of lower point-like conductive electrodes 162 composed of the carbon-doped gallium arsenide epitaxial layer 150 and the ohmic-contact metal layer 160. Please refer to FIG. 12, which is a top view of the light emitting diode 2 of the present invention in FIG. 11. It shows the non-overlapping arrangement of the upper electrode 190 and the lower point-like conductive electrodes 162 in the vertical distribution. In this way, the design of the upper and lower electrodes not only achieves the purpose of spreading the current but also prevents the light emitted from the light-emitting layer from being blocked by the upper electrode 190, thereby improving light extraction efficiency.

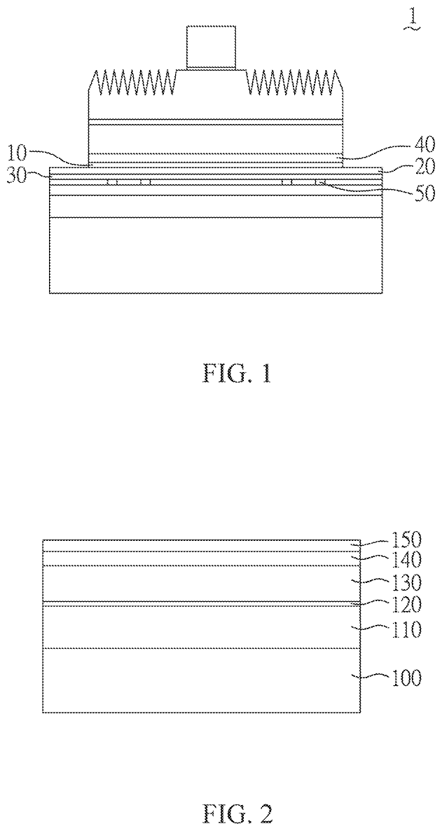

In summary, the disclosed short-wave infrared light emitting diode structure of the present invention has at least the following advantages. First, the lattice of the P-type carbon-doped gallium arsenide epitaxial layer 150 and the upper aluminum indium phosphide epitaxial layer 140 can match. Therefore, a patterned layer of P-type carbon-doped gallium arsenide epitaxial layer 150 can directly replace the three-layer structure of the conventional light emitting diode structure, including the transition layer, the P-type magnesium-doped gallium phosphide epitaxial layer, and the P-type carbon-doped gallium phosphide epitaxial layer. Thus, the epitaxial structure of the light emitting diode and its manufacturing process will be simplified and the production cost will be reduced. Second, the P-type carbon-doped gallium arsenide epitaxial layer 150 is patterned in correspondence to the lower ohmic-contact metal layer 160. It forms a new reflective mirror system with the transparent conductive layer and the reflective metal layer. Since the distribution area of the point-like P-type carbon-doped gallium arsenide epitaxial layer 150 is significantly reduced, accounting for only 2.8%˜5.2% of the overall epitaxial composite layer area after the MESA process, it effectively improves the problem of light absorption in the entire conventional structure of the carbon-doped gallium phosphide epitaxial layer as shown in FIG. 1. This substantially enhances the overall brightness of the light emitting diode. Third, the material of the P-type carbon-doped gallium arsenide epitaxial layer contributes to reducing the forward voltage compared to the conventional carbon-doped gallium phosphide epitaxial layer.

The above embodiments are provided for illustrative purposes and to explain the technical features of the present invention, and are not intended to limit the scope of protection of the present invention. Any modifications or equivalents that can be easily made by those skilled in the art are within the scope claimed by the present invention, and the scope of protection of the present invention shall be determined by the scope of the patent application.

What is claimed is:

1. A light emitting diode, comprising:
a plurality of point-like conductive electrodes;
a dielectric layer disposed around each of the point-like conductive electrodes, and
an epitaxial composite layer disposed both on the point-like conductive electrodes and the dielectric layer, wherein each of the point-like conductive electrodes includes an ohmic-contact metal layer and a carbon-doped gallium arsenide epitaxial layer and the carbon-doped gallium arsenide epitaxial layer is disposed on the ohmic-contact metal layer and electrically connected to the epitaxial composite layer.

2. The light emitting diode of claim 1, wherein the epitaxial composite layer includes a first semiconductor layer, a light-emitting layer, a second semiconductor layer and a third semiconductor layer, the third semiconductor layer is electrically connected to the carbon-doped gallium arsenide epitaxial layer, the second semiconductor layer is disposed on the third semiconductor, the light-emitting layer is disposed on the second semiconductor layer, and the first semiconductor layer is disposed on the light-emitting layer.

3. The light emitting diode of claim 2, wherein the first semiconductor layer is an N-type aluminum gallium arsenide (AlGaAs) epitaxial layer, and the second semiconductor layer is a P-type aluminum gallium arsenide (AlGaAs) epitaxial layer, and the third semiconductor layer is a P-type aluminum indium phosphide (AlInP) epitaxial layer.

4. The light emitting diode of claim 1, wherein the ratio of the total distribution area of the point-like conductive electrodes to the area of the epitaxial composite layer is about 2.8% to 5.2%.

5. The light emitting diode of claim 1, wherein the thickness of the carbon-doped gallium arsenide epitaxial layer in each of the point-like conductive electrodes is about 100˜1000 angstroms (Å).

6. The light emitting diode of claim 1, wherein the carbon-doping concentration of the carbon-doped gallium arsenide epitaxial layer in each of the point-like conduction electrodes is about 4.0*E19˜1.5*E20.

7. The light emitting diode of claim 1, further comprising a reflective layer, wherein the dielectric layer and the point-like conductive electrodes are disposed on the reflective layer.

8. The light emitting diode of claim 7, wherein the reflective layer includes a transparent conductive layer and a reflective metal layer, and the transparent conductive layer is disposed on the reflective metal layer.

9. The light emitting diode of claim 8, wherein the transparent conductive layer is made of indium tin oxide, zinc aluminum oxide, zinc tin oxide, nickel oxide, cadmium tin oxide, antimony tin oxide or the combination thereof.

10. The light emitting diode of claim 7, further comprising a substrate, wherein the reflective layer is disposed on the substrate.

11. The light emitting diode of claim 1, wherein the ohmic-contact metal layer is made of gold (Au), silver (Ag), aluminum (Al), beryllium gold (BeAu), germanium gold (GeAu), zinc gold (AuZn) or the combination thereof.

12. The light emitting diode of claim 1, further comprising an upper electrode disposed on the epitaxial composite layer without vertically overlapping with the point-like conductive electrodes.
